(19) United States
(12) Patent Application Publication
(10) Pub. No.: US 2025/0174469 A1
(43) Pub. Date: May 29, 2025

(54) SEMICONDUCTOR MANUFACTURING PROCESS, SEMICONDUCTOR DEVICE, AND SUBSTRATE PROCESSING APPARATUS

(71) Applicant: SEMES CO., LTD., Cheonan-si (KR)

(72) Inventors: Sang Man PARK, Cheonan-si (KR); Seong Kwang LEE, Cheonan-si (KR); Yong Hoon SUNG, Cheonan-si (KR); Hahn Joo YOON, Cheonan-si (KR); Il Young KIM, Cheonan-si (KR); Tae Wan KIM, Cheonan-si (KR); In Hoe KIM, Cheonan-si (KR); Thomas Jong Wan KWON, Cheonan-si (KR); CHENGYEH HSU, Cheonan-si (KR)

(73) Assignee: SEMES CO., LTD., Cheonan-si (KR)

(21) Appl. No.: 18/957,759

(22) Filed: Nov. 23, 2024

(30) Foreign Application Priority Data
Nov. 24, 2023 (KR) 10-2023-0165838

(51) Int. Cl. H01L 21/3213; H01J 37/32; H10B 43/35

(52) U.S. Cl. CPC H01L 21/32136; H01J 37/32201; H01J 37/3244; H10B 43/35

(57) ABSTRACT

Disclosed are a semiconductor manufacturing process capable of preventing residues from remaining, preventing a pattern from collapsing, controlling selectivity, and optimizing surface roughness, a semiconductor device manufactured through the semiconductor manufacturing process, and a substrate processing apparatus configured to perform the semiconductor manufacturing process. The semiconductor manufacturing process is performed to remove an oxide-nitride-oxide (ONO) layer formed on an outer side of a vertical layer in a horizontal space between a substrate and a base layer in a semiconductor pattern.

### CROSS-REFERENCE TO RELATED APPLICATION(S)

This application claims priority under 35 U.S.C. § 119 to Korean Patent Application No. 10-2023-0165838, filed on Nov. 24, 2023 in the Korean Intellectual Property Office, the disclosure of which is incorporated by reference herein in its entirety.

### BACKGROUND OF THE INVENTION

### Technical Field

The present disclosure relates to a semiconductor manufacturing process, a semiconductor device manufactured through the semiconductor manufacturing process, and a substrate processing apparatus configured to perform the semiconductor manufacturing process.

### Description of the Related Art

In order to meet excellent performance and low price demanded by consumers, the degree of integration of semiconductor devices is increasing. Therefore, three-dimensional semiconductor devices having a plurality of memory cells arranged in three dimensions (stereoscopically) are being developed. Such a three-dimensional semiconductor device is manufactured through tens to hundreds of steps of a semiconductor manufacturing process. A semiconductor manufacturing process is performed by several substrate processing apparatuses installed in a clean room.

Referring to FIG. 1, in a semiconductor manufacturing process for manufacture of a three-dimensional semiconductor device, a semiconductor pattern SP, which includes a substrate S, a base layer BL1 spaced a predetermined distance from the substrate S while defining a horizontal space HS therebetween, a horizontal layer HL including a plurality of oxide films OL and a plurality of nitride films NL alternately formed on the base layer BL1, a vertical layer VL extending from the substrate S in a vertical direction D3 while penetrating the horizontal layer HL and the base layer BL1, and a slit SL as a vertical space extending through the horizontal layer HL and the base layer BL1 in the vertical direction D3, is formed. A process for removing an oxide-nitride-oxide (ONO) layer L1 formed on an outer side of the vertical layer VL in the horizontal space HS between the substrate S and the base layer BL1 may be performed on the semiconductor pattern SP shown in FIG. 1.

A wet etching method is employed as a general method of removing the ONO layer L1. According to the wet etching method, an etchant EL, which reacts with the ONO layer L1, is supplied to the slit SL, and the ONO layer L1 is removed through reaction with the etchant EL. However, in this wet etching method, residues RS may remain and adhere to an inner wall of the slit SL, as shown in FIG. 2. During a process for drying the etchant EL, the pattern may collapse due to surface tension of a solvent. Because it is difficult to control ion concentration of the etchant EL, it is difficult to control selectivity with respect to materials. As shown in FIG. 1, when the etchant EL volatilizes, the vertical layer VL may be damaged, resulting in deterioration of surface roughness.

### SUMMARY

Therefore, the present disclosure has been made in view of the above problems, and it is an object of the present disclosure to provide a semiconductor manufacturing process capable of preventing residues from remaining, preventing a pattern from collapsing, controlling selectivity, and optimizing surface roughness, a semiconductor device manufactured through the semiconductor manufacturing process, and a substrate processing apparatus configured to perform the semiconductor manufacturing process.

In accordance with an aspect of the present disclosure, the above and other objects can be accomplished by the provision of a semiconductor manufacturing process for removing an oxide-nitride-oxide (ONO) layer formed on an outer side of a vertical layer in a horizontal space between a substrate and a base layer in a semiconductor pattern, including the substrate, the base layer spaced a predetermined distance from the substrate while defining the horizontal space therebetween, a horizontal layer including a plurality of oxide films and a plurality of nitride films alternately formed on the base layer, the vertical layer extending from the substrate in a vertical direction while penetrating the horizontal layer and the base layer, and a slit as a vertical space extending through the horizontal layer and the base layer in the vertical direction. The semiconductor manufacturing process includes an inhibition layer deposition step of supplying a halogen element having an alkyl group to the slit to form an inhibition layer on an inner wall of the slit, a plasma etching step of etching the ONO layer, and an inhibition layer removal step of removing the inhibition layer through thermal treatment.

In the embodiment of the present disclosure, the halogen element having the alkyl group may be —R(—CnH2n 1), where R may be F, Cl, Br, or I.

In the embodiment of the present disclosure, in the inhibition layer deposition step, the halogen element may be bonded to an inner wall surface of the slit.

In the embodiment of the present disclosure, the alkyl group may be formed on an outer side of the halogen element to passivate an inner wall of the slit.

In the embodiment of the present disclosure, the plasma etching step may include a surface modification step of supplying a halogen material to the slit to form a modification layer on a surface of the ONO layer, an adsorption step of injecting a precursor into the slit to form an adsorption layer on a surface formed of the alkyl group in the slit and the surface of the ONO layer, and a desorption step of supplying an etchant in a plasma state to etch the adsorption layer and the ONO layer.

In the embodiment of the present disclosure, the halogen material may be supplied to the slit in a gaseous state or a plasma state.

In the embodiment of the present disclosure, in the surface modification step, modification reaction in the slit may be inhibited by the alkyl group formed on a surface of the slit.

In the embodiment of the present disclosure, the surface modification step, the adsorption step, and the desorption step may be repeatedly performed two or more times.

In the embodiment of the present disclosure, the etchant may include at least one of O, H₂, NF₃, He, Ar, NH₃, or Cl₂.

In the embodiment of the present disclosure, a ratio of ions to radicals may be controlled through plasma control to control etching selectivity with respect to materials in the ONO layer.

In accordance with another aspect of the present disclosure, there is provided a semiconductor device manufactured through the semiconductor manufacturing process described above.

In accordance with a further aspect of the present disclosure, there is provided a substrate processing apparatus including a chamber configured to define therein a processing space for a substrate, a plasma generation module configured to generate plasma in the processing space, a microwave generation module configured to transmit microwaves to the processing space, and a gas supply module configured to supply process gas to the processing space. The substrate processing apparatus performs a semiconductor manufacturing process for removing an oxide-nitride-oxide (ONO) layer formed on an outer side of a vertical layer in a horizontal space between a substrate and a base layer in a semiconductor pattern, including the substrate, the base layer spaced a predetermined distance from the substrate while defining the horizontal space therebetween, a horizontal layer including a plurality of oxide films and a plurality of nitride films alternately formed on the base layer, the vertical layer extending from the substrate in a vertical direction while penetrating the horizontal layer and the base layer, and a slit as a vertical space extending through the horizontal layer and the base layer in the vertical direction.

The semiconductor manufacturing process includes an inhibition layer deposition step of supplying, by the gas supply module, a halogen element having an alkyl group to the processing space to form an inhibition layer on an inner wall of the slit, a plasma etching step of supplying, by the gas supply module, process gas to the processing space and generating, by the plasma generation module, plasma in the chamber to etch the ONO layer, and an inhibition layer removal step of supplying, by the microwave generation module, microwave power to the processing space to remove the inhibition layer through thermal treatment.

The plasma etching step includes a surface modification step of supplying a halogen material to the slit to change characteristics of a surface of the ONO layer, an adsorption step of injecting a precursor into the slit to form an adsorption layer on the surface of the ONO layer, and a desorption step of supplying an etchant in a plasma state to etch the adsorption layer and the ONO layer.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a view showing a process for removing an oxide-nitride-oxide (ONO) layer according to a related art;

FIG. 2 is a view showing a state in which residues adhere to an inner wall of a slit in the process for removing an ONO layer according to the related art;

FIG. 3 is a flowchart showing a semiconductor manufacturing process for removing an ONO layer formed on an outer side of a vertical layer in a semiconductor pattern according to the present disclosure;

FIG. 4 is a flowchart showing a plasma etching step in the semiconductor manufacturing process according to the present disclosure;

FIG. 5 is a view showing a semiconductor pattern to which the semiconductor manufacturing process according to the present disclosure is applied;

FIGS. 6 and 7 are views showing a state in which an inhibition layer is formed on an inner wall of a slit in the semiconductor pattern;

FIG. 8 is a view showing a state in which a modification layer is formed on a surface of the ONO layer;

FIG. 9 is a view showing a state in which an adsorption layer is formed on the surface of the ONO layer;

FIG. 10 is a view showing a state in which the ONO layer is etched;

FIG. 11 is a view showing a state in which an inhibition layer is removed;

FIG. 12 is a view for explaining a semiconductor device manufactured through the semiconductor manufacturing process according to the present disclosure;

FIG. 13 is a view for explaining a portion of a memory block of the semiconductor device shown in FIG. 12;

FIG. 14 is an enlarged view of area A in FIG. 13; and

FIG. 15 is a view showing the structure of a substrate processing apparatus configured to perform the semiconductor manufacturing process according to the present disclosure.

### DETAILED DESCRIPTION

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

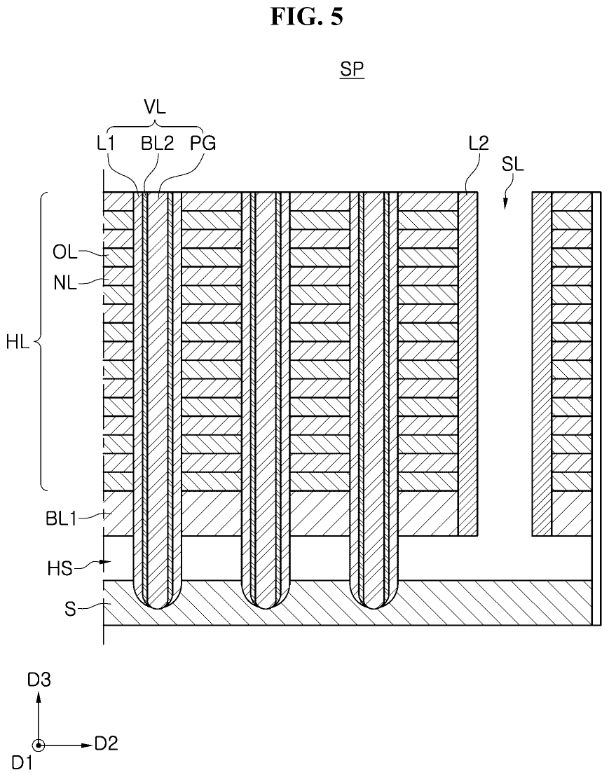

The present disclosure relates to a semiconductor manufacturing process, a semiconductor device manufactured through the semiconductor manufacturing process, and a substrate processing apparatus configured to perform the semiconductor manufacturing process. As shown in FIG. 5, a semiconductor pattern SP, which includes a substrate S, a base layer BL1 spaced a predetermined distance from the substrate S while defining a horizontal space HS therebetween, a horizontal layer HL including a plurality of oxide films OL and a plurality of nitride films NL alternately formed on the base layer BL1, a vertical layer VL extending from the substrate S in a vertical direction D3 while penetrating the horizontal layer HL and the base layer BL1, and a slit SL as a vertical space extending through the horizontal layer HL and the base layer BL1 in the vertical direction D3, is formed. This semiconductor pattern SP is formed in a process for manufacturing a three-dimensional semiconductor device such as a flash memory.

Referring to FIG. 5, the base layer BL1 is formed on the silicon substrate S while being spaced a predetermined distance therefrom. The base layer BL1 corresponds to an etch-blocking layer. The oxide films OL, such as SiO₂, and the nitride films NL, such as Si₃N₄, are alternately stacked on the base layer BL1 to form the horizontal layer HL. In FIG. 5, a first direction D1 and a second direction D2 are directions parallel to the substrate S, and are directions perpendicular to each other. Each of the first direction D1 and the second direction D2 is referred to as a horizontal direction. A third direction D3 is a direction perpendicular to the substrate S, and is referred to as a vertical direction.

The vertical layer VL is formed so as to extend from the substrate S in the vertical direction D3 while penetrating the base layer BL1 and the horizontal layer HL. The vertical layer VL includes a gate layer PG formed at a central portion thereof and made of polysilicon (poly-Si), an etch-blocking layer BL2 formed on an outer side of the gate layer PG, and an oxide-nitride-oxide (ONO) layer L1 formed on an outer side of the etch-blocking layer BL2. The ONO layer L1 refers to a layer composed of block oxide, trap nitride, and tunnel oxide in a memory having one transistor cell as an information storage unit.

In the semiconductor pattern SP, the slit SL is formed as a vertical space extending through the horizontal layer HL and the base layer BL1 in the vertical direction D3. An empty space is defined in the slit SL, and an ONO layer L2 is formed on an inner wall of the slit SL.

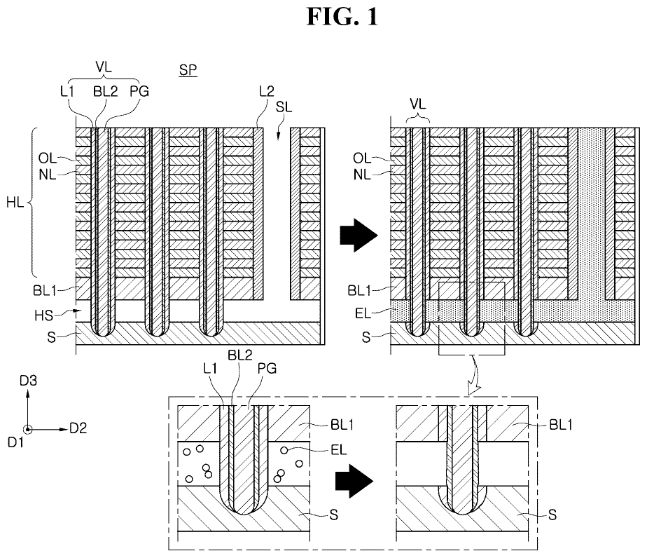

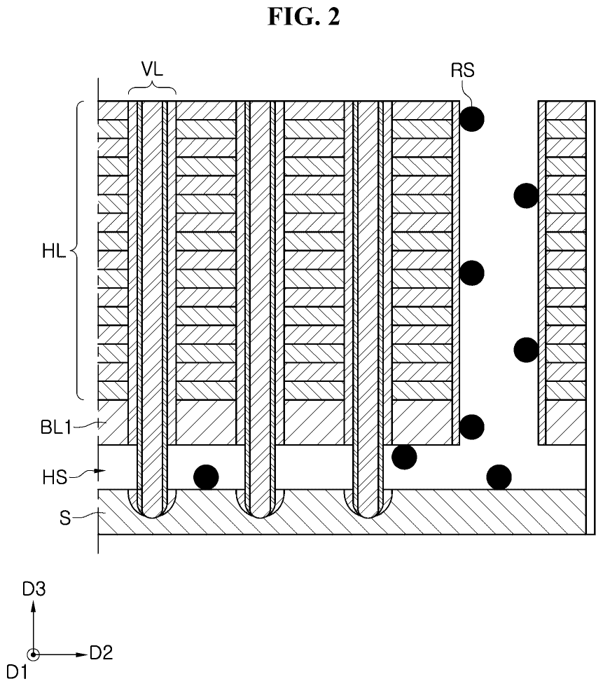

The semiconductor manufacturing process of the present disclosure is proposed to remove the ONO layer L1 formed on an outer side of the vertical layer VL in the horizontal space HS between the substrate S and the base layer BL1 in the semiconductor pattern SP. Compared to the related art in which a liquid etchant EL is used as shown in FIGS. 1 and 2, the semiconductor manufacturing process of the present disclosure exhibits effects of preventing the pattern from collapsing, enabling control of selectivity, and optimizing surface roughness.

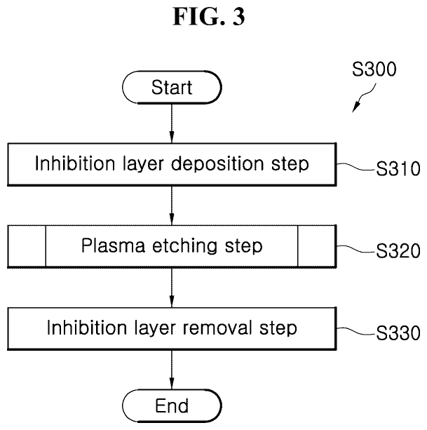

FIG. 3 is a flowchart showing the semiconductor manufacturing process for removing the ONO layer L1 formed on an outer side of the vertical layer VL in the semiconductor pattern SP according to the present disclosure. The semiconductor manufacturing process S300 according to the present disclosure includes an inhibition layer deposition step S310 of supplying a halogen element HA having an alkyl group AG to the slit SL to form an inhibition layer IL on an inner wall of the slit SL, a plasma etching step S320 of etching the ONO layer L1, and an inhibition layer removal step S330 of removing the inhibition layer IL through thermal treatment.

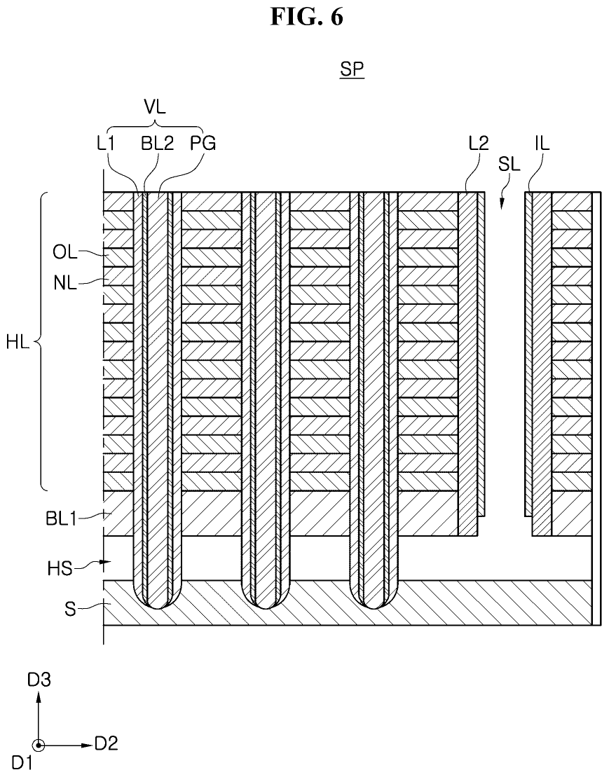

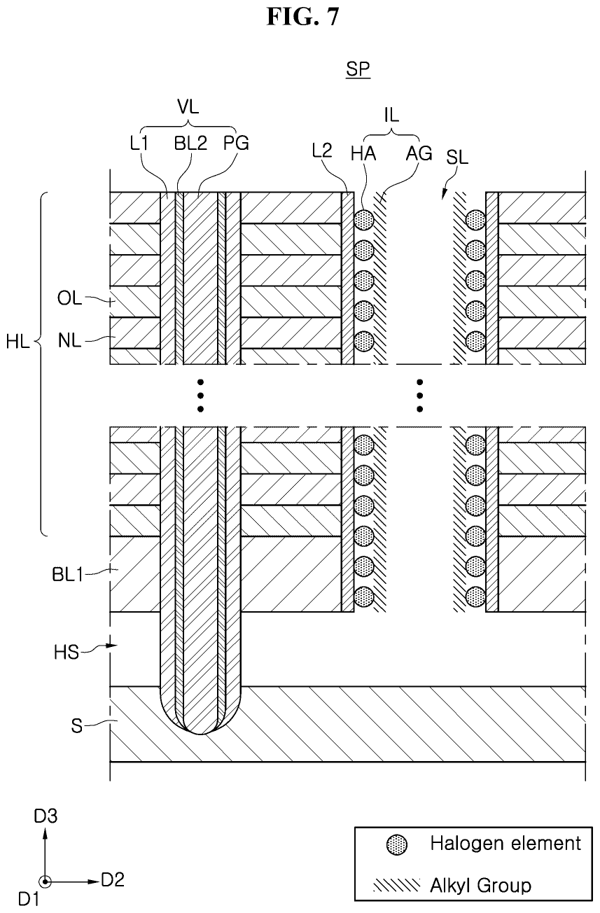

In the inhibition layer deposition step S310, a halogen element HA having an alkyl group AG is supplied to the slit SL in the semiconductor pattern SP. The halogen element HA having an alkyl group AG may be —R(—CnH2n 1), where R may be F, Cl, Br, or I. The inhibition layer IL is formed on an inner wall surface of the slit SL in the inhibition layer deposition step S310, as shown in FIG. 6. FIG. 7 is an enlarged view of the slit SL shown in FIG. 6. Referring to FIG. 7, the inhibition layer IL is formed on an outer side of the ONO layer L2 on the inner wall surface of the slit SL. In the inhibition layer IL, the halogen element HA having high electron affinity is bonded to the ONO layer L2 on the inner wall surface of the slit SL, and the alkyl group AG is located on an opposite side, i.e., a side close to the center of the slit SL. Since the alkyl group AG is formed on an outer side of the halogen element HA, the inner wall of the slit SL may be passivated.

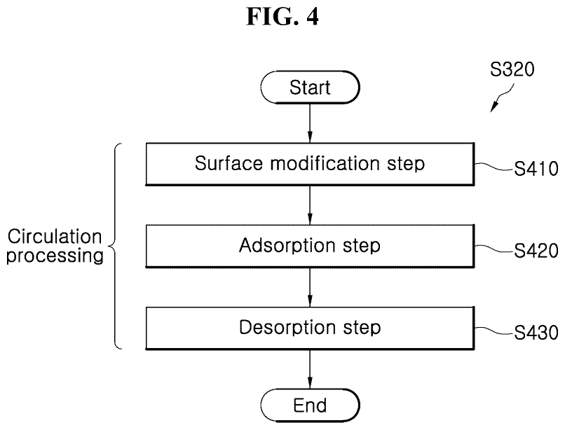

The inhibition layer IL is formed on the inner wall surface of the slit SL, and the ONO layer L1 of the vertical layer VL is etched in the plasma etching step S320. FIG. 4 is a flowchart showing the plasma etching step S320 in the semiconductor manufacturing process according to the present disclosure. The plasma etching step S320 includes a surface modification step S410 of supplying a halogen material to the slit SL to form a modification layer ML on a surface of the ONO layer L1, an adsorption step S420 of injecting a precursor into the slit SL to form an adsorption layer AL on the surface of the ONO layer L1, and a desorption step S430 of supplying an etchant in a plasma state to remove the adsorption layer AL and the ONO layer L1.

In the surface modification step S410, a halogen material is supplied to the slit SL to form a modification layer ML on the surface of the ONO layer L1. Here, the halogen material may be supplied to the slit SL in a gaseous state or a plasma state. That is, plasma of a halogen element or halogen-based gas may be supplied to the slit SL. In the surface modification step S410, modification reaction in the slit SL is inhibited by the alkyl group AG formed on the inner wall surface of the slit SL. Thus, the modification layer ML is formed on an outer side of the ONO layer L1, but no modification layer is formed on the inner wall surface of the slit SL. The modification layer ML serves as a layer that induces bonding of the precursor in the subsequent adsorption step S420.

In the adsorption step S420, a precursor is supplied to the slit SL, and an adsorption layer AL is formed on a surface of the ONO layer L1. The precursor is bonded to the modification layer ML formed on the surface of the ONO layer L1 to form the adsorption layer AL. On the other hand, the adsorption layer AL is not formed on the surface of the slit SL.

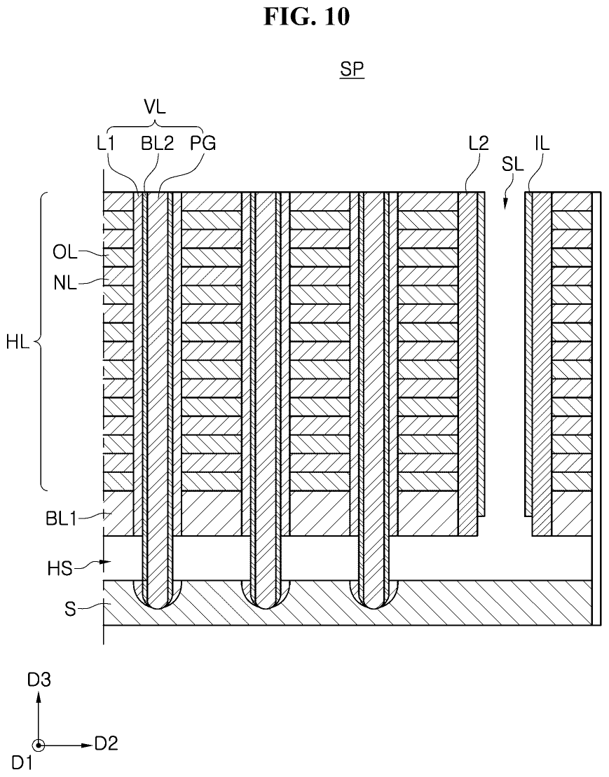

In the desorption step S430, as shown in FIG. 10, an etchant in a plasma state is supplied to the slit SL to remove the adsorption layer AL and the ONO layer L1. The etchant may include at least one of oxygen (O), hydrogen (H₂), nitrogen fluoride (NF₃), helium (He), argon (Ar), nitrogen hydroxide (NH₃), or chlorine (Cl₂). In the desorption step S430, a ratio of ions to radicals is controlled through plasma control, whereby etching selectivity with respect to materials in the ONO layer L1 may be controlled.

As the adsorption layer AL is desorbed by the etchant, the ONO layer L1 is etched. Formation of the adsorption layer AL on the ONO layer L1 and removal of the ONO layer L1 may be performed in units of atomic layers. That is, the ONO layer L1 may be removed through atomic layer etching (ALE). In order to achieve atomic layer etching, the surface modification step S410, the adsorption step S420, and the desorption step S430 may be repeatedly performed two or more times.

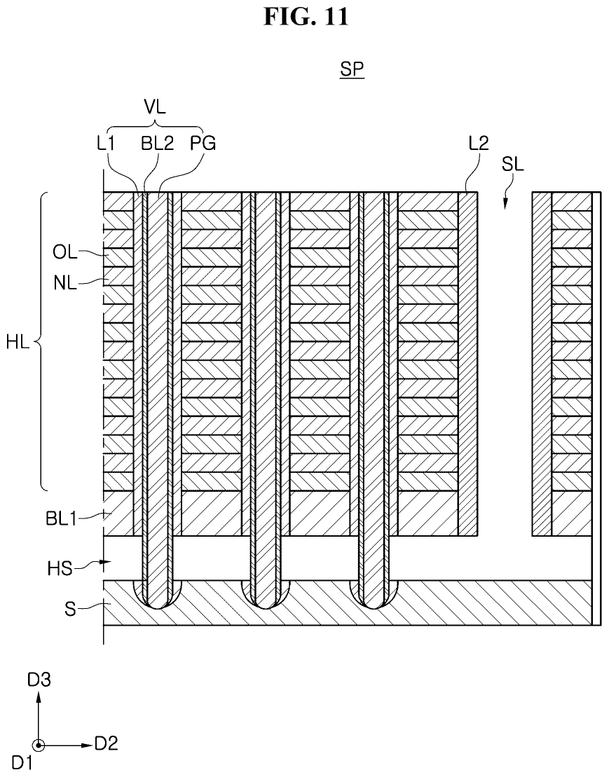

When the plasma etching step S320 is completed, as shown in FIG. 11, the inhibition layer IL is removed through thermal treatment in the inhibition layer removal step S330. For example, the inhibition layer IL may be removed through a reactive ion etching (RIE) process. Additionally, purge gas may be supplied to remove internal residues.

According to the present disclosure described above, the ONO layer L1 is removed through an ALE process, and the inhibition layer IL is formed on the inner wall of the slit SL, whereby residues, i.e., particles remaining in the horizontal space HS or the slit SL, may be removed. In addition, unlike wet etching, no liquid is used, and thus it is possible to prevent collapse of the pattern and damage to the surface attributable to volatilization of moisture. In addition, selectivity in the etching process is controlled through plasma control, and thus it is possible to achieve fineness of the process.

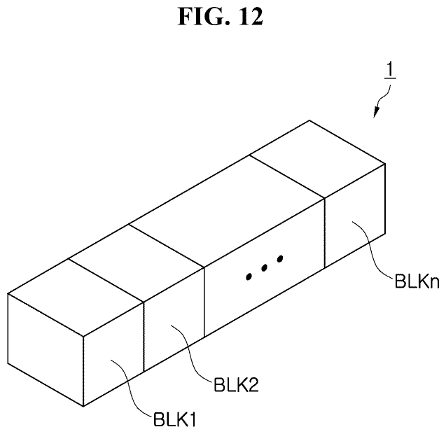

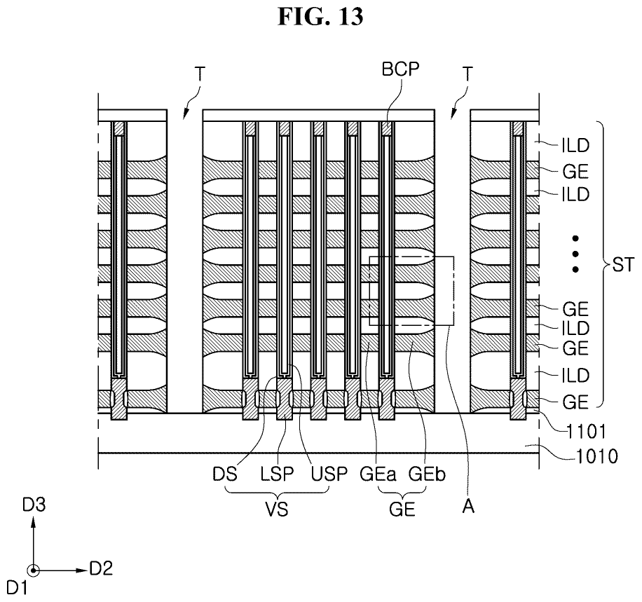

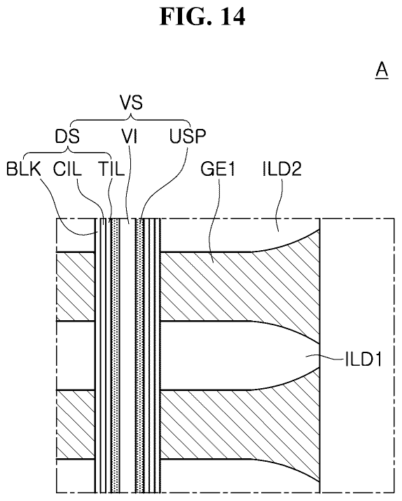

FIG. 12 is a view for explaining a semiconductor device 1 manufactured through the semiconductor manufacturing process according to the present disclosure. FIG. 13 is a view for explaining a portion of a memory block of the semiconductor device 1 shown in FIG. 12. FIG. 14 is an enlarged view of area A in FIG. 13. The semiconductor device 1 of the present disclosure may be a NAND flash memory.

Referring to FIG. 12, a memory cell array of the semiconductor device 1 according to the present disclosure includes a plurality of memory blocks BLK1 to BLKn (where n is a natural number).

Referring to FIG. 13, a plurality of electrode structures ST is disposed on a substrate 1010. The electrode structures ST may extend parallel to each other in the horizontal direction.

The substrate 1010 may be one of a material having semiconductor properties (e.g., silicon wafer), an insulative material (e.g., glass), a semiconductor covered with an insulative material, or a conductor. A buffer insulating film 1101 may be interposed between the electrode structures ST and the substrate 1010, and may include a silicon oxide film.

Each of the electrode structures ST may include a plurality of gate electrodes GE and a plurality of insulating films ILD alternately stacked in the vertical direction. The three-dimensional semiconductor memory may be a vertical NAND flash memory, and the gate electrodes GE of each of the electrode structures ST may be used as gate electrodes of a string selection transistor, a memory cell transistor, and a ground selection transistor of NAND cell strings.

The thickness of the insulating films ILD may be varied depending on the characteristics of the semiconductor memory device. The insulating films ILD may include, for example, a silicon oxide film or a low-k dielectric film.

The gate electrodes GE may be made of one selected from among metal (e.g., tungsten, copper, or aluminum), a doped semiconductor (e.g., doped silicon), conductive metal nitride (e.g., titanium nitride or tantalum nitride), and transition metal (e.g., titanium or tantalum).

A plurality of vertical structures VS may extend in the vertical direction D3 perpendicular to the upper surface of the substrate 1010, and may penetrate each of the electrode structures ST. The vertical structures VS may be arranged in a zigzag form in the first direction D1 and the second direction D2 when viewed in plan.

Each of the vertical structures VS may include vertical semiconductor patterns LSP and USP connected to the substrate 1010 and a data storage pattern (i.e., charge storage film) DS interposed between the vertical semiconductor patterns LSP and USP and the electrode structures ST. Further, a bit line conductive pad BCP made of a conductive material may be provided on the upper end of each of the vertical structures VS. In an example, the bit line conductive pad BCP may be made of a semiconductor material doped with impurities.

The vertical semiconductor patterns LSP and USP may include a semiconductor material such as silicon (Si), germanium (Ge), or a mixture thereof. The vertical semiconductor patterns LSP and USP may be used as channels of ground and string selection transistors and memory cell transistors in a vertical NAND flash memory device. Here, the vertical semiconductor patterns LSP and USP may include a lower semiconductor pattern LSP, which is in contact with the substrate 1010 while penetrating a lower portion of each of the electrode structures ST, and an upper semiconductor pattern USP, which is in contact with the lower semiconductor pattern LSP while penetrating an upper portion of each of the electrode structures ST. The lower semiconductor pattern LSP may be an epitaxial pattern, and may have a pillar shape. The upper semiconductor pattern USP may have a U-shape having an empty space defined therein, a pipe shape having a closed lower end, or a macaroni shape. The interior of the upper semiconductor pattern USP may be filled with an embedded insulating pattern.

As shown in FIG. 14, the data storage pattern (i.e., charge storage film) DS is a data storage film of a vertical NAND flash memory device, and may include a tunnel insulating film TIL, a charge storage film CIL, and a blocking insulating film BLK.

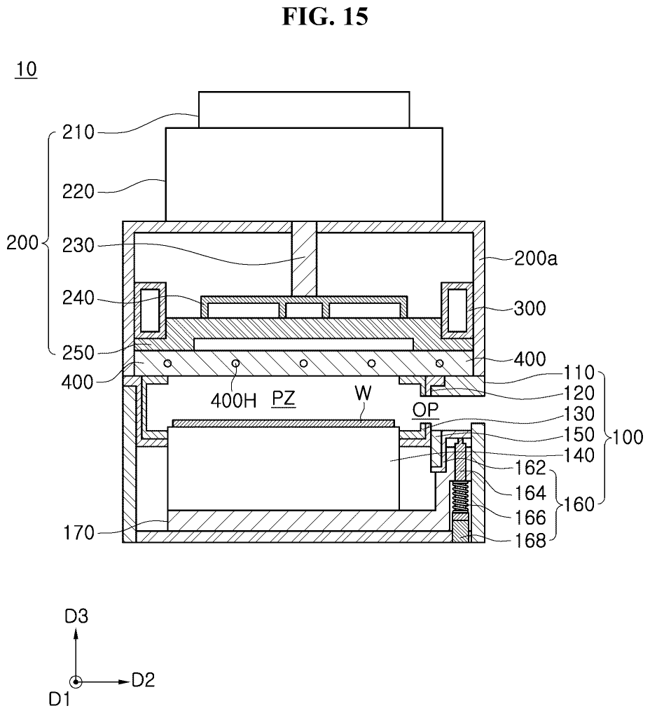

FIG. 15 shows the structure of a substrate processing apparatus 10 configured to perform the semiconductor manufacturing process according to the present disclosure.

Rapid heating and cooling are required in plasma treatment such as atomic layer deposition (ALD) and atomic layer etching (ALE). As a semiconductor process is getting finer, ALD and ALE processes have become important, and heating treatment using microwaves is employed in order to achieve rapid heating.

FIG. 15 shows the substrate processing apparatus 10 according to the present disclosure. The substrate processing apparatus 10 may perform a process for heating a substrate W using microwave power. Additionally, the substrate processing apparatus 10 may perform plasma treatment (e.g., dry etching and deposition) along with thermal treatment of the substrate W. That is, the substrate processing apparatus 10 may alternately perform thermal treatment and a plasma treatment process on the substrate W.

The substrate processing apparatus 10 includes a chamber 100 configured to define therein a processing space PZ for the substrate W, a plasma generation module 200 configured to generate plasma in the processing space PZ, a microwave generation module 300 configured to transmit microwaves to the processing space PZ, and a gas supply module 400 configured to supply process gas to the processing space PZ.

The chamber 100 is located at a lower portion of the substrate processing apparatus 10, and is composed of a plurality of parts defining the processing space PZ for the substrate W. The chamber 100 includes a chamber housing 110, a heater liner 120 mounted to the chamber housing 110 and including a plurality of first exhaust holes formed in a lower surface thereof, an inner liner 130 mounted inside the heater liner 120 and including a second exhaust hole formed in a lower surface thereof, a substrate support member 140 disposed inside the inner liner 130 and configured to support the substrate W, a shutter liner 150 configured to open or close an opening OP defined by the sidewalls of the heater liner 120 and the inner liner 130, and a shutter driving unit 160 configured to raise or lower the shutter liner 150.

The chamber housing 110 is a structure that surrounds outer sides of parts of the chamber 100. The parts constituting the chamber 100 may be mounted in the chamber housing 110. An opening OP through which the substrate W passes may be formed in a portion of the chamber housing 110.

The heater liner 120 is coupled to the chamber housing 110. The heater liner 120 is made of a metal. The heater liner 120 may be made of an alloy containing aluminum (Al). A ring-shaped heater configured to emit heat may be provided inside the heater liner 120. The heater liner 120 is formed in a ring shape.

The inner liner 130 is coupled to an inner side of the heater liner 120 to define the processing space PZ. The inner liner 130 is made of ceramic. The inner liner 130 may be made of quartz. Fire polishing treatment may be performed on a surface of the inner liner 130. Because the inner liner 130 is made of quartz and undergoes fire polishing treatment, the inner liner 130 has excellent chemical resistance against process gas (Cl₂) and excellent surface roughness. The inner liner 130 having the above properties surrounds the processing space PZ.

The substrate support member 140 is located at an inner lower portion of the inner liner 130. The substrate support member 140 supports the substrate W at a position below the substrate W. The substrate support member 140 attracts and tightly holds the substrate W using electrostatic force. A heater and a refrigerant flow path are provided inside the substrate support member 140 in order to control the temperature of the substrate W. The substrate support member 140 may include a lower electrode configured to generate an electromagnetic field in the processing space PZ together with an antenna 240.

The shutter liner 150 may selectively open or close the opening OP defined by the sidewalls of the heater liner 120 and the inner liner 130. The shutter liner 150 may have the same size and shape as the opening OP defined by the sidewalls of the heater liner 120 and the inner liner 130. The shutter liner 150 may be raised or lowered by the shutter driving unit 160. When the substrate W is introduced into the processing space PZ, the shutter liner 150 may be lowered to open the opening OP, and when a treatment process is commenced after introduction of the substrate W, the shutter liner 150 may be raised to close the opening OP.

The shutter driving unit 160 is linked to the shutter liner 150 to raise or lower the shutter liner 150. The shutter driving unit 160 includes a shutter bracket 162 fastened to the shutter liner 150, a vertical driving shaft 164 coupled to the shutter bracket 162, a bellows 166 coupled to an outer side of the vertical driving shaft 164, and a cylinder driving source 168 configured to supply driving force for raising or lowering the vertical driving shaft 164. The shutter liner 150 is a part designed to be in contact with plasma, and may be made of quartz. Fire polishing treatment may also be performed on a surface of the shutter liner 150.

The plasma generation module 200 generates plasma in the processing space PZ in order to perform processing on the substrate. The plasma generation module 200 may include an RF power supply 210, a matcher 220, an RF rod 230, an antenna 240, and a window 250. The RF power supply 210 generates power of a specific frequency to generate plasma. The matcher 220 is connected to the RF power supply 210, and controls impedance of an internal circuit so that the power generated by the RF power supply 210 is transmitted to the processing space PZ as efficiently as possible. The RF rod 230 is connected to the matcher 220 to transmit the power having passed through the RF power supply 210 and the matcher 220 to the antenna 240. The antenna 240 is connected to the RF rod 230 to generate an electromagnetic field in the processing space PZ using the power supplied through the RF rod 230. The window 250 is located under the antenna 240 to support the antenna 240, and may be made of a dielectric material so that an electromagnetic field is generated in the processing space PZ in the chamber 100 by the antenna 240. The window 250 may be formed in a shape covering the upper side of the chamber 100.

The microwave generation module 300 provides microwaves for thermal treatment of the substrate W to the processing space PZ. The microwave generation module 300 may include a microwave power supply (not shown) and a microwave antenna configured to radiate microwaves supplied from the microwave power supply to the processing space PZ. The microwave antenna may be located at an edge of an upper surface of the window 250. The microwave antenna may be located in contact with an upper housing 200a.

The gas supply module 400 supplies gas to the processing space PZ. The gas supply module 400 is connected to an external gas source to spray process gas (e.g., Cl₂) to the interior of the processing space PZ. The gas supply module 400 may be formed in a ring shape and may be located between the antenna 240 and the chamber 100. The ring-shaped gas supply module 400 includes a plurality of gas supply holes 400H formed therein, and process gas is supplied to the processing space PZ through the gas supply holes 400H.

The substrate processing apparatus 10 performs a semiconductor manufacturing process S300 for removing an ONO layer L1 formed on an outer side of a vertical layer VL in a horizontal space HS between a substrate S and a base layer BL1 in a semiconductor pattern SP, which includes the substrate S, the base layer BL1 spaced a predetermined distance from the substrate S while defining the horizontal space HS therebetween, a horizontal layer HL including a plurality of oxide films OL and a plurality of nitride films NL alternately formed on the base layer BL1, the vertical layer VL extending from the substrate S in the vertical direction while penetrating the horizontal layer HL and the base layer BL1, and a slit SL as a vertical space extending through the horizontal layer HL and the base layer BL1 in the vertical direction.

The semiconductor manufacturing process S300 performed by the substrate processing apparatus 10 includes an inhibition layer deposition step S310 of supplying, by the gas supply module 400, a halogen element HA having an alkyl group AG to the processing space PZ to form an inhibition layer IL on an inner wall of the slit SL, a plasma etching step S320 of supplying, by the gas supply module 400, process gas to the processing space PZ and generating, by the plasma generation module 200, plasma in the processing space PZ to etch the ONO layer L1, and an inhibition layer removal step S330 of supplying, by the microwave generation module 300, microwave power to the processing space PZ to remove the inhibition layer IL through thermal treatment.

The plasma etching step S320 includes a surface modification step S410 of supplying a halogen material to the slit SL to change the characteristics of a surface of the ONO layer L1, an adsorption step S420 of injecting a precursor into the slit SL to form an adsorption layer AL on the surface of the ONO layer L1, and a desorption step S430 of supplying an etchant in a plasma state to etch the adsorption layer AL and the ONO layer L1. The surface modification step S410, the adsorption step S420, and the desorption step S430 may be repeatedly performed two or more times.

In the inhibition layer deposition step S310, the halogen element HA having an alkyl group AG may be —R(—CnH2n 1), where R may be F, Cl, Br, or I. The halogen element HA having an alkyl group AG may be supplied to the processing space PZ in the chamber 100 through the gas supply module 400.

In the inhibition layer deposition step S310, as shown in FIG. 7, the halogen element HA may be bonded to the inner wall surface of the slit SL. Since the alkyl group AG is formed on an outer side of the halogen element HA, the inner wall of the slit SL may be passivated.

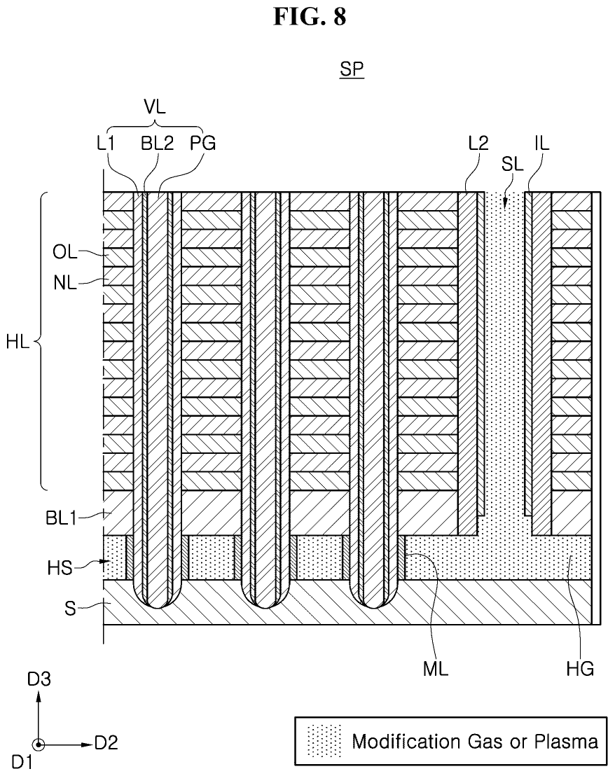

In the surface modification step S410, as shown in FIG. 8, the halogen material may be supplied to the slit SL in a gaseous state or a plasma state. A halogen gas may be supplied to the processing space PZ in the chamber 100 through the gas supply module 400. The halogen gas may become a plasma state by the plasma generation module 200. The modification layer ML may be formed on a surface of the ONO layer L1 by the halogen gas. Modification reaction in the slit SL may be inhibited by the alkyl group AG formed on the inner wall surface of the slit SL.

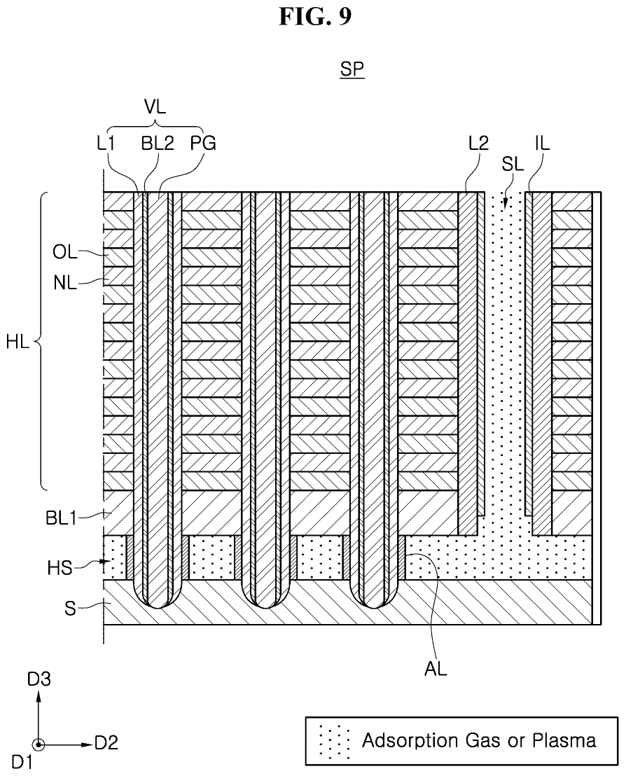

In the adsorption step S420, as shown in FIG. 9, a precursor may be injected into the slit SL to form an adsorption layer AL on a surface of the ONO layer L1. Process gas including the precursor is supplied through the gas supply module 400. In addition, the process gas including the precursor may become a plasma state through the plasma generation module 200.

In the desorption step S430, as shown in FIG. 10, an etchant in a plasma state is supplied to etch the adsorption layer AL and the ONO layer L1. Etching gas including at least one of O, H₂, NF₃, He, Ar, or NH₃ may be supplied to the processing space PZ through the gas supply module 400, and the adsorption layer AL and the ONO layer L1 may be etched by the etchant having become a plasma state through the plasma generation module 200. In this case, a ratio of ions to radicals is controlled through control of the plasma generation module 200, whereby etching selectivity with respect to materials in the ONO layer L1 may be controlled.

In the inhibition layer removal step S330, the inhibition layer IL is removed through thermal treatment. The thermal treatment may be performed through supply of microwave power to the processing space PZ by the microwave generation module 300. Alternatively, the inhibition layer IL may be removed through a reactive ion etching (RIE) process. Additionally, purge gas may be supplied to remove internal residues.

As is apparent from the above description, according to the present disclosure, an oxide-nitride-oxide (ONO) layer is removed through an atomic layer etching process, thus making it possible to prevent residues from remaining, prevent a pattern from collapsing, control selectivity, and optimize surface roughness.

Although the preferred embodiments of the present disclosure have been disclosed for illustrative purposes, those skilled in the art will appreciate that various modifications, additions and substitutions are possible, without departing from the scope and spirit of the invention.

The scope of the present disclosure should be defined only by the accompanying claims, and all technical ideas within the scope of equivalents to the claims should be construed as falling within the scope of the invention.

What is claimed is:

1. A semiconductor manufacturing process for removing an oxide-nitride-oxide (ONO) layer formed on an outer side of a vertical layer in a horizontal space between a substrate and a base layer in a semiconductor pattern, comprising the substrate, the base layer spaced a predetermined distance from the substrate while defining the horizontal space therebetween, a horizontal layer comprising a plurality of oxide films and a plurality of nitride films alternately formed on the base layer, the vertical layer extending from the substrate in a vertical direction while penetrating the horizontal layer and the base layer, and a slit as a vertical space extending through the horizontal layer and the base layer in the vertical direction, the semiconductor manufacturing process comprising:
an inhibition layer deposition step of supplying an alkyl group having a halogen element to the slit to form an inhibition layer on an inner wall of the slit;
a plasma etching step of etching the ONO layer; and
an inhibition layer removal step of removing the inhibition layer through thermal treatment.

2. The semiconductor manufacturing process according to claim 1, wherein the halogen element comprising the alkyl group is —R(—CnH2n 1), where R is F, Cl, Br, or I.

3. The semiconductor manufacturing process according to claim 1, wherein, in the inhibition layer deposition step, the halogen element is bonded to an inner wall surface of the slit.

4. The semiconductor manufacturing process according to claim 3, wherein the alkyl group having the halogen element is formed to passivate an inner wall of the slit.

5. The semiconductor manufacturing process according to claim 1, wherein the plasma etching step comprises:
a surface modification step of supplying a halogen material to the slit to form a modification layer on a surface of the ONO layer;
an adsorption step of injecting a precursor into the slit to form an adsorption layer on a surface formed of the alkyl group in the slit and the surface of the ONO layer; and
a desorption step of supplying an etchant in a plasma state to etch the adsorption layer and the ONO layer.

6. The semiconductor manufacturing process according to claim 5, wherein the halogen material is supplied to the slit in a gaseous state or a plasma state.

7. The semiconductor manufacturing process according to claim 5, wherein, in the surface modification step, modification reaction in the slit is inhibited by the alkyl group formed on a surface of the slit.

8. The semiconductor manufacturing process according to claim 5, wherein the surface modification step, the adsorption step, and the desorption step are repeatedly performed two or more times.

9. The semiconductor manufacturing process according to claim 5, wherein the etchant comprises at least one of O, H₂, NF₃, He, Ar, NH₃, or Cl₂.

10. The semiconductor manufacturing process according to claim 5, wherein a ratio of ions to radicals is controlled through plasma control to control etching selectivity with respect to materials in the ONO layer.

11. A semiconductor device manufactured through the semiconductor manufacturing process according to claim 1.

12. A substrate processing apparatus comprising:
a chamber configured to define therein a processing space for a substrate;
a plasma generation module configured to generate plasma in the processing space;
a microwave generation module configured to transmit microwaves to the processing space; and
a gas supply module configured to supply process gas to the processing space,
wherein the substrate processing apparatus performs a semiconductor manufacturing process for removing an oxide-nitride-oxide (ONO) layer formed on an outer side of a vertical layer in a horizontal space between a substrate and a base layer in a semiconductor pattern, comprising the substrate, the base layer spaced a predetermined distance from the substrate while defining the horizontal space therebetween, a horizontal layer comprising a plurality of oxide films and a plurality of nitride films alternately formed on the base layer, the vertical layer extending from the substrate in a vertical direction while penetrating the horizontal layer and the base layer, and a slit as a vertical space extending through the horizontal layer and the base layer in the vertical direction,
wherein the semiconductor manufacturing process comprises:
an inhibition layer deposition step of supplying, by the gas supply module, a halogen element comprising an alkyl group to the processing space to form an inhibition layer on an inner wall of the slit;
a plasma etching step of supplying, by the gas supply module, process gas to the processing space and generating, by the plasma generation module, plasma in the chamber to etch the ONO layer; and
an inhibition layer removal step of supplying, by the microwave generation module, microwave power to the processing space to remove the inhibition layer through thermal treatment, and
wherein the plasma etching step comprises:
a surface modification step of supplying a halogen material to the slit to change characteristics of a surface of the ONO layer;
an adsorption step of injecting a precursor into the slit to form an adsorption layer on the surface of the ONO layer; and
a desorption step of supplying an etchant in a plasma state to etch the adsorption layer and the ONO layer.

13. The substrate processing apparatus according to claim 12, wherein the halogen element comprising the alkyl group is —R(—CnH2n 1), where R is F, Cl, Br, or I.

14. The substrate processing apparatus according to claim 12, wherein, in the inhibition layer deposition step, the halogen element is bonded to an inner wall surface of the slit.

15. The substrate processing apparatus according to claim 14, wherein the alkyl group having the halogen element is formed to passivate an inner wall of the slit.

16. The substrate processing apparatus according to claim 12, wherein the halogen material is supplied to the slit in a gaseous state or a plasma state.

17. The substrate processing apparatus according to claim 12, wherein, in the surface modification step, modification reaction in the slit is inhibited by the alkyl group formed on an inner wall surface of the slit.

18. The substrate processing apparatus according to claim 12, wherein the surface modification step, the adsorption step, and the desorption step are repeatedly performed two or more times.

19. The substrate processing apparatus according to claim 15, wherein the etchant comprises at least one of O, H₂, NF₃, He, Ar, NH₃, or Cl₂.

20. The substrate processing apparatus according to claim 12, wherein a ratio of ions to radicals is controlled through control of the plasma generation module to control etching selectivity with respect to materials in the ONO layer.
